(19) United States
(12) Patent Application Publication
(10) Pub. No.: US 2003/0194510 A1
(43) Pub. Date: Oct. 16, 2003

(54) Methods used in fabricating gates in integrated circuit device structures

(75) Inventors: Huong Thanh Nguyen, San Ramon, CA (US); Michael Barnes, San Ramon, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/124,014

(22) Filed: Apr. 16, 2002

(51) Int. Cl. C23C 16/00

(52) U.S. Cl. 427/569; 427/255.28

(57) ABSTRACT

One embodiment of the present invention is a method used to fabricate devices on a substrate, which method is utilized at a stage of processing wherein a dummy gate that includes gate electrode material and gate dielectric material is exposed, which method includes steps of: (a) flowing one or more gases into a plasma generator disposed outside a processing chamber containing the substrate; and (b) flowing output from the plasma generator into the processing chamber so that the substrate is exposed to species that selectively etch the gate electrode material.

### TECHNICAL FIELD OF THE INVENTION

One or more embodiments of the present invention pertain to methods for use in fabricating gates in integrated circuit device structures.

### BACKGROUND OF THE INVENTION

Threshold voltage deviation in sub-100 nm metal oxide semiconductor field effect transistors (MOSFETs) is a serious problem whose origin is considered to be due to, among others things, fluctuation in gate length, fluctuation in gate oxide thickness, fluctuation in channel impurity density, boron penetration from a polysilicon gate to a channel, polysilicon gate depletion, work function deviation of the gate material, and the presence of interface traps and fixed charge in the gate oxide. Interface traps and fixed charge in the gate oxide are created during fabrication from the use of a plasma process such as a reactive ion etch (“RIE”) process, and the use of an ion implantation process. Further, polysilicon gate depletion is often accelerated by impurity deactivation during thermal processing after gate formation. Therefore, it is important to reduce plasma-induced and thermal-induced damage to gate structures.

The use of a metal gate and a high dielectric constant (“high-k”) gate dielectric in fabricating MOSFETs may be important in the sub-100 nm regime because metal gate and high-k gate dielectric technology could provide low gate resistance (and thereby, a higher speed device), no gate depletion (and thereby, a reduction of the electrical gate oxide thickness), no boron penetration into the channel, and low gate leakage current. However, metal gate and high-k gate dielectric materials are easily degraded by high temperature processes such as activation annealing for source/drain formation (about 1000° C.).

An article by A. Yagishita et al. entitled “Improvement of Threshold Voltage Deviation in Damascene Metal Gate Transistors” in IEEE Transactions on Electron Devices, Vol. 48, No. 8, pp. 1604-1611, August 2001 (the “Yagishita article”) discloses a “plasma- and thermal-damage-free gate formation process (damascene process)” to reduce threshold voltage deviation, and processes to fabricate MOSFETs using metal gate and high-k gate dielectric technology. As disclosed therein, the term thermal-damage means degradation of gate oxide integrity (large gate leakage current, short Time Dependent Dielectric Breakdown (“TDDB”) lifetime, and so forth) caused by reactions between a metal gate and a gate oxide or by metal gate diffusion into the gate oxide. In addition, the term plasma-damage means interface state generation or degradation in the TDDB lifetime of the gate oxide.

In the Yagishita article, in accordance with the disclosed damascene gate process, the gate oxide and the gate electrode are fabricated after the source/drain are formed. As shown in FIG. 1 of the Yagishita article, a dummy gate (including a dummy gate oxide and a dummy gate electrode) is replaced with a newly grown gate (including a newly grown gate insulator—for example, high-k materials or SiO₂—and a metal gate electrode) after: (a) ion implanting the source/drain (the implanting is self-aligned to the dummy gate); and (b) high temperature annealing for source/drain activation. The gate electrodes are fabricated by chemical mechanical polishing (“CMP”) of metal gate materials deposited in grooves that are formed by removing the dummy gate. As a result of the disclosed damascene gate process, plasma- and thermal-damage of the gate electrode and the gate oxide are reduced because: (a) there is no plasma-damage caused by source/drain ion implantation and RIE processes; and (b) processing temperatures after gate formation can be reduced to as low as about 600° C.

However, the Yagishita article does not describe a method for removing the dummy gate structure without causing damage to the gate oxide or the substrate.

### SUMMARY OF THE INVENTION

One or more embodiments of the present invention advantageously satisfy the above-identified need in the art. Specifically, one embodiment of the present invention is a method used to fabricate devices on a substrate, which method is utilized at a stage of processing wherein a dummy gate that includes gate electrode material and gate dielectric material is exposed, which method includes steps of: (a) flowing one or more gases into a plasma generator disposed outside a processing chamber containing the substrate; and (b) flowing output from the plasma generator into the processing chamber so that the substrate is exposed to species that selectively etch the gate electrode material.

### BRIEF DESCRIPTION OF THE FIGURE

FIG. 1 shows a block diagram of a cross section of a wafer or substrate having devices being fabricated thereon (a work-in-progress), which work-in-progress is at a stage of processing where dummy gates have been exposed; and

FIG. 2 shows a cross-sectional side view of an apparatus that may be used to carry out one or more embodiments of the present invention.

### DETAILED DESCRIPTION

The Yagishita article discloses a metal oxide semiconductor field effect transistor (“MOSFET”) device having: (a) a metal gate electrode fabricated from, for example, and without limitation, Al/TiN or W/TiN, (for example where the TiN is sputtered or is deposited using chemical vapor deposition); and (b) a gate dielectric fabricated from, for example, and without limitation, SiO₂, SiON (oxynitride), or Ta₂O₅/SiON dielectrics. One embodiment of the present invention is a method for use in fabricating the MOSFET device having the structure disclosed in the Yagishita article.

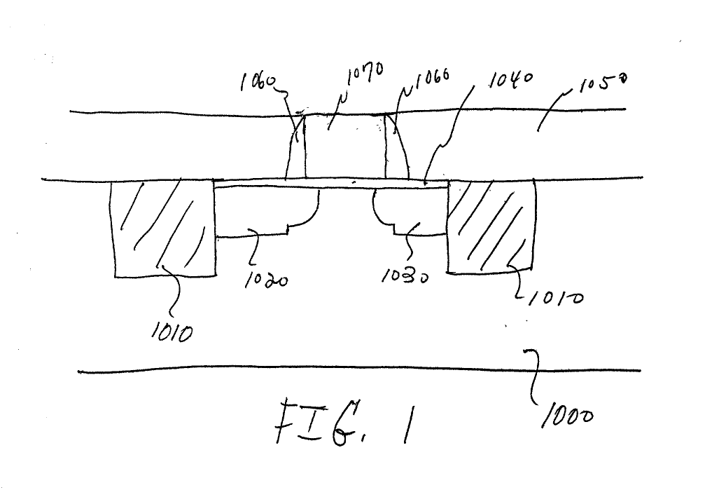

As shown in the Yagishita article (refer to FIG. 1 of the Yagishita article), the MOSFET device may be fabricated by: (a) forming a dummy gate (comprising for example, a gate oxide and a polysilicon gate electrode); (b) forming gate spacers (for example, Si₃N₄ spacers) by conventional processes; (c) forming source/drains areas by conventional processes; (d) forming premetal dielectric (for example, a “TEOS” silicon oxide) by conventional processes; and (e) planarizing the resulting structure using, for example, chemical mechanical polishing (“CMP”) to expose the polysilicon. As is well known, spacers typically comprise nitride, and are typically covered by an oxide barrier to protect them from subsequent processing. Next, the dummy gate, or at least a portion thereof, is removed in accordance with one or more embodiments of the present invention.

FIG. 1 shows a block diagram of a cross section of a wafer or substrate having devices being fabricated thereon (a work-in-progress), which work-in-progress is at a stage of processing (also shown in FIG. 1 of the Yagishita article, after step 2) where dummy gates have been exposed. As shown in FIG. 1, wafer or substrate 1000 (for example, silicon wafer or substrate 1000) includes isolation structures 1010, source 1020, drain 1030, pre-metal dielectric 1050, gate spacers 1060, and a dummy gate that includes gate oxide 1040 and gate electrode 1070. In accordance with one embodiment of the present invention, wafer 1000 is placed into a processing chamber such as, for example, and without limitation, a processing chamber wherein a plasma is generated outside of the processing chamber using any one of a number of methods that are well known to one of ordinary skill in the art. For example, in accordance with one embodiment of the present invention, a remote plasma generator is used wherein a gas flows through a tube that is exposed to microwaves output from a microwave generator in accordance with any one of a number of methods that are well known to those of ordinary skill in the art. Then, the plasma which is formed in the tube flows through a gas line into the chamber through a gas distribution box. The plasma then enters the chamber through channels in, for example, a top plate in the chamber (for example, the top plate may comprise a showerhead), or through inlet channels that are disposed to provide entrance channels for the plasma. Appropriate gas distribution mechanisms can be fabricated in accordance with any one of a number of methods that are well known to those of ordinary skill in the art. An appropriate distance between the remote plasma generator and the gas distribution box may be determined routinely by one of ordinary skill in the art without undue experimentation to provide a predetermined number distribution of various plasma species to be present inside the chamber. Further, appropriate ranges of microwave frequency and power, and gas pressure in the remote plasma generator may be determined routinely by one or ordinary skill in the art without undue experimentation. Still further, an exhaust pump for the chamber removes gas, and together with the flow rates for the plasma, is used to provide predetermined ranges of pressure with the chamber. Appropriate ranges of pressure may be determined routinely by one or ordinary skill in the art without undue experimentation.

In accordance with an alternative embodiment of the remote plasma generator, a gas flows into an entrance channel in a toroidal tube. A coil is wound about at least a portion of the tube, and the coil is energized by RF energy in accordance with any one of a number of methods that are well known to those of ordinary skill in the art to generate a plasma in the toroidal tube. The plasma gas flows out of an exit channel in the toroidal tube, through a gas line, and into the chamber through a gas distribution box. Appropriate ranges of RF frequency and power, and gas pressure in the remote plasma generator may be determined routinely by one or ordinary skill in the art without undue experimentation.

Advantageously, in accordance with these embodiments of the present invention, etching is provided predominantly by chemical reaction. The chemical etching process will remove gate electrode 1070 rapidly, without plasma damage to gate oxide 1040 (or to silicon substrate 1000 if it is desired to remove gate oxide 1040). In accordance with one embodiment of the present invention, precursor gases are chosen to provide a fast etch process that provides selectivity to gate spacers 1060 (typically gate spacers 1060 have an oxide barrier). For example, in accordance with one such embodiment, the use of CF₄ as a precursor provides rapid etching due to the formation of fluorine radicals (CF₄ provides good dissociation). In addition, in accordance with a further embodiment, CF₄ may be combined with one or more of O₂ and H₂ to enhance selectivity. In addition, in accordance with a further embodiment, one or more of Ar, He, and N₂ may also be used to dilute the plasma. Appropriate ranges of proportions of the precursor gases and the diluents may be determined routinely by one or ordinary skill in the art without undue experimentation. In accordance with another embodiment of the present invention, SF₆ may be used as a precursor gas. In addition, in accordance with a further embodiment, SF₆ may also be used together with one or more of CF₄, F-based gases, O₂, H₂, Ar, He, and N₂. In accordance with another embodiment of the present invention, Cl₂ may be used as a precursor gas. In addition, in accordance with a further embodiment, Cl₂ may also be used together with one or more of SF₆, CF₄, O₂, H₂, Ar, He, and N₂. In accordance with another embodiment, Cl-based gases may be used as a precursor gas. In addition, in accordance with a further embodiment, Cl-based gases may also be used together with one or more of Cl₂, SF₆, CF₄, F-based gases, O₂, H₂, Ar, He, and N₂. In accordance with another embodiment of the present invention, Br-based gases (for example, and without limitation, BrCl₃) may be used as a precursor gas. In addition, in accordance with another embodiment of the present invention, Br-based gases may also be used together with one or more of Cl-based gases, Cl₂, SF₆, CF₄, F-based gases, O₂, H₂, Ar, He, and N₂.

If a particular circuit design calls for removing gate oxide 1040, then the embodiments described above would be used as a first etch process step to remove gate electrode 1070. Next, a second etch process step would used to remove gate oxide 1040 with selectivity to substrate 1000. For example, in accordance with one embodiment of the present invention, precursors and diluents for use in the second etch process step would include the same gases described above for etching gate electrode 1070. However, the power used to generate a plasma (described in detail below) might be is lower than (for example, and without limitation, as much as one-half) the power used in the first etch process step; the chamber pressure might be higher than (for example, and without limitation, up to three times higher than) the chamber pressure used in the first etch process step; and/or the gas flow rates might be lower than (for example, and without limitation, as much as one-half) the gas flow rates used in the first etch process step. Further suitable ranges of power, chamber pressure, and gas flow rates may be determined routinely by one of ordinary skill in the art without undue experimentation

In accordance with one embodiment of the present invention, a suitable processing chamber is an Advanced Strip Process (“ASP”) chamber manufactured by Applied Materials, Inc. of Santa Clara, Calif. In accordance with such an embodiment, wafer or substrate 1000 is supported on a pedestal (also referred to as a susceptor), and the temperature of the pedestal is adjusted to cause the temperature of wafer 1000 to be in a range from about −20° C. to about +100° C. Further suitable ranges of temperature may be determined routinely by one of ordinary skill in the art without undue experimentation. The pressure in the chamber would be in a range from about 50 mT to about 10 Torr. Further suitable ranges of pressure may be determined routinely by one of ordinary skill in the art without undue experimentation. Power applied to a remote plasma generator would be in a range from about 200 Watts to about 4,000 Watts. Further suitable ranges of power may be determined routinely by one of ordinary skill in the art without undue experimentation. Lastly, etching gases that are passed through the remote plasma generator include Cl₂-based gases, Br-based gases, F-based gases, or combinations of one or more of them. In addition, other diluent gases may be used in addition to the etching gases, for example, and without limitation, one or more of Ar, He, N₂, and O₂. The flow rates of the etching gases would be in a range from about 20 sccm to about 1000 sccm, and the flow rates of the other diluent gases would be in a range from about 50 sccm to about 5000 sccm. Further suitable ranges of gas flow rates may be determined routinely by one of ordinary skill in the art without undue experimentation.

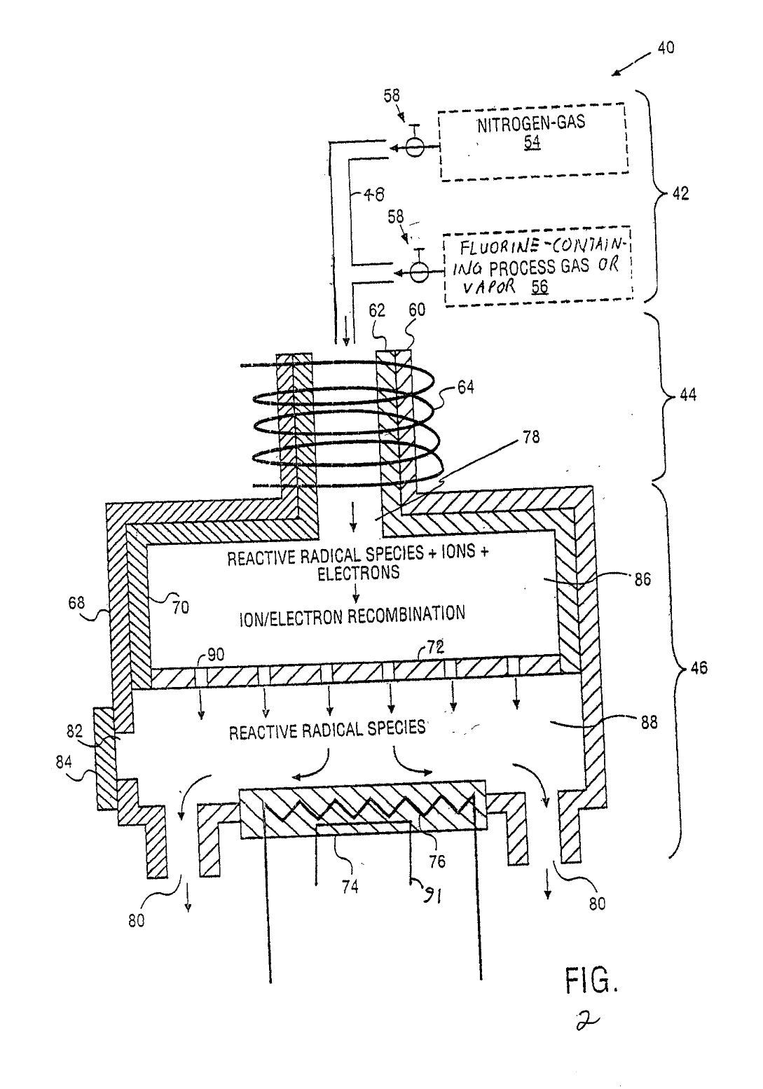

FIG. 2 shows a cross-sectional side view of apparatus 40 that may be used to carry out an embodiment of the present invention. As shown in FIG. 2, apparatus 40 includes gas supply apparatus 42, apparatus 44 for energizing the gas mixture, and substrate processing apparatus 46. As further shown in FIG. 2, illustratively, gas supply apparatus 42 includes supply line 48, source of a fluorine-containing process gas 56, and optionally source of nitrogen gas 54. A respective valve 58 connects a respective source 54 and 56 to supply line 48.

Apparatus 44 creates reactive radical species by coupling the gas mixture with an electromagnetic field that is remote from the substrate. Apparatus 44 includes pass-through pipe 60, quartz liner 62 on an inner surface of pipe 60, and coil 64 that spirals around pipe 60. Supply line 48 feeds into an upper end of pipe 60, the center of coil 64 is located within pipe 60. The material of pipe 60 and the quartz of quartz liner 62 allow the electromagnetic field generated by coil 64 to penetrate within pipe 60. In one embodiment of the present invention, reactive radical species are created by energizing a mixture of gases with a radio frequency, inductively coupled, plasma. A microwave source may alternatively be used to create a microwave-coupled plasma. It is also possible to utilize a toroidal radio-frequency-based source to create a radio frequency inductively coupled plasma. Other apparatuses may exist that can generate reactive radical species out of a mixture as described.

Substrate processing apparatus 46 includes processing chamber 68, liner 70 (e.g., quartz), baffle 72, substrate stand 74, resistive heating element 76, and cooling line 91. As can be understood, coating of pipe 60 and walls of processing chamber 68 may be used instead of liners 62, 70.

As shown in FIG. 2, processing chamber 68 has inlet opening 78 in an upper wall thereof, and outlet openings 80 in a lower wall thereof. Chamber 68 also has slit 82 in one sidewall thereof. Slit 82 can be opened and closed using slit valve 84.

Quartz liner 70 is located on the upper walls of processing chamber 68, and on sidewalls of processing chamber 68. Optionally, a liner or coating may be added to the lower walls of chamber 68. Baffle 72 is located between the upper wall and the lower wall, and separates chamber 68 into settling cavity 86, and exposure cavity 88. Baffle 72 is entirely made of quartz, and has a plurality of baffle openings 90 formed therein.

A lower end of pipe 60 feeds into inlet opening 78 of processing chamber 68. A gas can flow from supply line 48 through pipe 60 into settling cavity 86, and then through baffle openings 90 into exposure cavity 88 of processing chamber 68. The gas is only exposed to containing walls formed by quartz liner 62, quartz liner 70, and quartz of baffle 72 from the time the gas enters pipe 60 until it exits through baffle openings 90 into exposure cavity 88.

Substrate stand 74 is located within the lower wall of processing chamber 68, and has an upper horizontal surface located within exposure cavity 88 of processing chamber 68. A substrate can be located on the upper horizontal surface of substrate stand 74. Resistive element 76 is located within substrate stand 74. A current flowing through resistive element 76 heats substrate stand 74, and the upper surface thereof.

Better etching results can be obtained when apparatuses 44 and 46 are conditioned by pre-heating. It is believed that reactivity between the quartz and the energized gas mixture is reduced within apparatuses 44 and 46, and that such reactivity is reduced further when quartz liners 62 and 70 and the quartz of baffle 72 are preheated. Minimal reactivity from bulk or surface recombination reactions increases the quantity of reactive species available to react with the substrate. Quartz liners 62 and 70 and the quartz of baffle 72 may be preheated by exposing them to a plasma, or by directly heating them using heating coils or lamps.

Current is also provided through resistive element 76 so that resistive element 76 heats substrate stand 74. A cooling fluid in cooling line 91 maintains the temperature of substrate stand 74 at a desired level.

When liners 62 and 70 and baffle 72 reach an appropriate surface temperature, and substrate stand 74 reaches an appropriate temperature, valves 58 are closed and current to coil 64 is switched off. Chamber 68 is then filled with an inert gas, typically nitrogen gas 54. For purposes of further discussion it should be assumed that these temperatures are maintained throughout further processing.

Slit valve 84 is then moved so that slit 82 is opened. The substrate is then located on a blade, and carried on the blade through slit valve 84 into exposure cavity 88. The blade positions substrate 10 on the upper surface of substrate stand 74. The blade is thereafter removed through slit valve 84, and slit 82 is closed by slit valve 84.

Heat transfers from resistive element 76 to substrate stand 74, and from substrate stand 74 to the substrate. An alternating current is provided through coil 64 to create a radio frequency field within a core of pipe 60.

Valves 58 are subsequently opened so that gases 54 and 56 flow into and mix in supply line 48. The mixture of gases then flows from supply line 48, through pipe 60 and chamber 68 out of outlet openings 80. A pump is connected to outlet openings 80 to maintain an appropriate pressure within chamber 68. A plasma is formed in pipe 60 (including reactive radical species, ions, electrons and neutrals), which plasma flows through inlet opening 78 into settling cavity 86. The ions combine rapidly with the electrons while the plasma is within settling cavity 86. A result of the ion-electron recombination is that the ion density is substantially reduced. The density of the radical species is also reduced (although to a much lesser degree than the ions) because of surface and bulk recombination. The rate of recombination is decreased by the quartz of liners 62 and 70 and quartz of the baffle 72. The mixture, including the reactive radical species remaining therein, then flows through baffle openings 90 to exposure cavity 88. Substantially no ions reach exposure cavity 88. The reactive radical species then react with the material of gate electrode 1070.

Although embodiments of the present method were described for a structure wherein the dummy gate comprises a gate oxide and polysilicon, other embodiments exist wherein the dummy gate comprises a high-k gate dielectric and polysilicon. In such embodiments, an embodiment of the present invention would entail etching the polysilicon with etching species that are selective to the underlying high-k gate dielectric, such as the use of the precursor gases, and under the processing conditions, set forth above.

Further steps of fabricating the MOSFET are described in the Yagishita article. However, as disclosed in the Yagishita article, the physical length of the damascene gate is determined by inside edges of the sidewalls of gate spacers 1060 (for example, Si₃N₄ sidewalls). This is identical to the case of a conventional polysilicon gate formed by RIE in which thermal SiO₂ or oxynitride is used as a gate insulator. However, the physical gate length in the damascene transistor is shorter than that for the conventional polysilicon gate in a case where the gate insulator is formed by a deposition technique (i.e., a case where gate insulator coats the sidewalls of the gate spacer).

Those skilled in the art will recognize that the foregoing description has been presented for the sake o illustration and description only. As such, it is not intended to be exhaustive or to limit the invention to the precise form disclosed. For example, although certain dimensions were discussed above, they are merely illustrative since various designs, may be fabricated using the embodiments described above, and the actual dimensions for such designs will be determined in accordance with circuit requirements.

What is claimed is:

1. A method used to fabricate a device on a substrate, which method is utilized at a stage of processing wherein a dummy gate that includes gate electrode material and gate dielectric material is exposed, which method comprises steps of:
flowing one or more gases into a plasma generator disposed outside a processing chamber containing the substrate; and
flowing output from the plasma generator into the processing chamber so that the substrate is exposed to species that selectively etch the gate electrode material.

2. The method of claim 1 wherein the species substantially comprise radicals.

3. The method of claim 1 which further comprises steps of:
flowing further one or more gases into the plasma generator; and
flowing output from the plasma generator into the chamber so that the wafer is exposed substantially to species that selectively etch the gate dielectric material.

4. The method of claim 3 wherein the species substantially comprise radicals.

5. The method of claim 1 which further includes steps of heating the wafer.

6. The method of claim 5 wherein the one or more gases include Cl-based gases, Br-based gases, F-based gases, or combinations of one or more of them.

7. The method of claim 6 wherein the one or more gases include one or more further gases that include Ar, He, N₂, O₂, or combinations of one or more of them.

8. The method of claim 6 wherein the wafer is heated to a temperature in a range from about −20° C. to about +100° C.

9. The method of claim 6 wherein a pressure in the processing chamber is provided in a range from about 50 mT to about 10 Torr.

10. The method of claim 6 wherein power is supplied to the plasma generator in a range from about 200 Watts to about 4,000 Watts.

11. The method of claim 6 wherein flow rates of the one or more gases are in a range from about 20 sccm to about 1000 sccm.

12. The method of claim 7 wherein flow rates of the one or more further gases are in a range from about 50 sccm to about 5000 sccm.

13. The method of claim 6 wherein the Cl-based gases include Cl₂.

14. The method of claim 6 wherein the F-based gases include CF₄ or SF₆.

15. The method of claim 6 wherein the Br-based gases include BrCl₃.

16. The method of claim 6 wherein the plasma generator includes a microwave generator.

17. The method of claim 6 wherein the plasma generator includes a radio frequency powered coil.

18. The method of claim 3 wherein the further one or more gases include Cl-based gases, Br-based gases, F-based gases, or combinations of one or more of them.

19. The method of claim 18 wherein a pressure in the processing chamber is higher than the pressure in the processing chamber when etching the gate electrode material.

20. The method of claim 18 wherein a flow rate of the further one or more gases is lower that the flow rate of the one or more gases.

21. The method of claim 18 wherein a power supplied to the plasma generator is lower that the power supplied when etching the gate electrode material.
